(19) United States
(12) Patent Application Publication
(10) Pub. No.: US 2013/0216731 A1
(43) Pub. Date: Aug. 22, 2013

(54) CONTROL OF DIFFERENTIAL PRESSURE IN PECVD SYSTEMS

(71) Applicant: Gregory Bugnon, Neuchatel (CH)

(72) Inventor: Gregory Bugnon, Neuchatel (CH)

(73) Assignee: TEL SOLAR AG, Trubbach (CH)

(21) Appl. No.: 13/820,180

(22) PCT Filed: Sep. 2, 2011
(86) PCT No.: PCT/CH2011/000203

§ 371 Date: May 2, 2013

Related U.S. Application Data
(60) Provisional application No. 61/379,897, filed on Sep. 3, 2010.

(51) Int. Cl. C23C 16/50

(52) U.S. Cl. CPC C23C 16/50
USPC 427/569; 118/723 R

(57) ABSTRACT

A method and apparatus for manufacturing thin films is described, wherein, in a deposition system comprising an inner non-airtight enclosure for containing at least one substrate, an outer airtight chamber completely surrounding said enclosure, an exhaust operatively connected to both, said inner chamber is kept at a pressure lower than the pressure within said outer enclosure, especially a pressure difference of less than I mbar. The apparatus may exhibit two butterfly vents arranged between inner enclosure, outer chamber and an exhaust for controlling said pressure difference.

This invention relates to improvements in depositing of thin films, especially thin silicon films, by means of plasma enhanced chemical vapor deposition (PECVD). In more detail it refers to improvements of a deposition process used in a parallel-plate reactor known in the art.

### BACKGROUND OF THE INVENTION

Device-grade a-Si:H materials grown by low temperature PECVD typically employ low pressure, low depletion deposition regimes. Large scale homogeneity is ensured by using a proper isothermal reactor, with efficient showerhead gas distribution system for controlling both gas preheating and gas composition over the whole substrate area before it enters the plasma region. Contamination issues during deposition can be circumvented through the use of a small leak gas conductance between the actual deposition chamber, where the plasma is properly confined, and the outer vacuum chamber: this allows the establishment of a differential pressure during deposition, with a higher pressure inside the deposition chamber.

U.S. Pat. No. 4,989,543 shows a deposition system allowing for operation under differential pressure conditions. It refers to an apparatus for producing thin films using a plasma deposit processing with a non-airtight enclosure in which the prevailing pressure is less than the atmospheric pressure for containing at least one substrate; means for creating a plasma zone containing said at least one substrate within said enclosure, an airtight chamber surrounding said enclosure, said chamber being kept at a pressure lower than the pressure within said enclosure. This inner non-airtight enclosure in an outer airtight chamber arrangement is also known in the art as Plasmabox reactor. U.S. Pat. No. 4,989,543 suggests a pressure of 10¹ Pa for the inner enclosure, whereas the outer chamber can be pumped down to approximately 10⁻⁴ to 10⁻⁵ Pa.

As of now, such or similar equipment are used for microcrystalline silicon (pc-Si:H) deposition at growth rate up to about 5 A/s, with typical deposition pressure of 2.5 mbar or below.

### DRAWBACKS IN PRIOR ART

However, growing μc-Si:H at higher pressure and/or higher depletion working conditions are typical prerequisites for reaching higher growth rates while keeping device grade quality material. Due to the presence of gas drag forces and much higher diffusivity of hydrogen compared to silane, local enrichment of the silane concentration near the leaks of the Plasmabox reactor will take place. This is especially favored at higher pressure differences between the outer chamber and plasma reaction chamber and, hence, enhanced at higher plasma operating pressures. This locally higher silane concentration favors the well known undesired powder formation in silane plasmas. This however is detrimental for both homogeneity and overall reproducibility as it can generate strong instabilities. As a result even localized powder formation sites at the peripheral edges of the inner plasma chamber can significantly affect the entire discharge electrical parameters and affect the quality of the deposited material (thickness, defects, crystallinity, quality of the material).

Non-uniformities and instabilities due to powder formation in these regimes are the limiting parameters to the growth of high quality material at high rate or very high pressure regimes in those large area reactors, even with narrow electrode gap configurations.

### DETAILS OF THE INVENTION

For PECVD systems using the differential pressure concept, the invention relates to the establishment of well defined pressure in the zone outside the deposition chamber in order to precisely control and adjust the immediate pressure drop ratio near the plasma region to avoid the local silane enrichment and limit gas drag forces: this will limit aforementioned problems due to powder formation while retaining a still controlled local pressure drop to refrain contamination from the outside.

Outer gas composition can be the same dilution or may also be controlled independently from what is injected in the plasma chamber, and pressure could be independently controlled by different means: for example using a butterfly valve on existing system or with properly defined gas leak conductance between the chambers, so that the pressure ratio can range from as low as possible to equilibrium. Other gases could as well be used to control this pressure drop (H₂, He, Ar, N₂, etc.)

For instance this controlled pressure drop can be achieved in current systems with a Plasmabox design by filling the entire outer volume with a gas at a pressure close to the one used in the deposition chamber so that the pressure difference becomes much smaller. New designs with an intermediate pressure zone in-between the plasma chamber and the outer chamber could also serve as a buffer zone (without plasma) to properly control both gas pressure drop and contamination.

As a result this solution allows the use of Plasmabox reactors at significantly higher working pressures and/or higher depletion regimes, allowing higher growth rates and better material quality over large surfaces without being so much limited with powder formation.

### DETAILED DESCRIPTION OF THE INVENTION

FIG. 1 shows the basic arrangement of a Plasmabox reactor. It shows an inner non-airtight enclosure 20 in which a prevailing pressure can be established lower than the atmospheric pressure. Means for creating a plasma zone containing at least one substrate within said enclosure have been omitted. An airtight chamber 10 surrounding said enclosure 20 is being kept, during operation, at a pressure lower than the pressure within said enclosure 20. A pumping line 30 acts as exhaust to both inner enclosure 20 and outer chamber 10. A butterfly vent 50 allows distributing the pumping effect between enclosures 20 and 10, such establishing the differential pressure between chamber 10 and enclosure 20.

Definition of differential pressure: ΔP=Pᵢₙ−Pₒᵤₜ·Pᵢₙ is the pressure in the volume where the plasma assisted (PECVD) deposition takes place and Pₒᵤₜ means the pressure in the vacuum chamber surrounding the PECVD reactor.

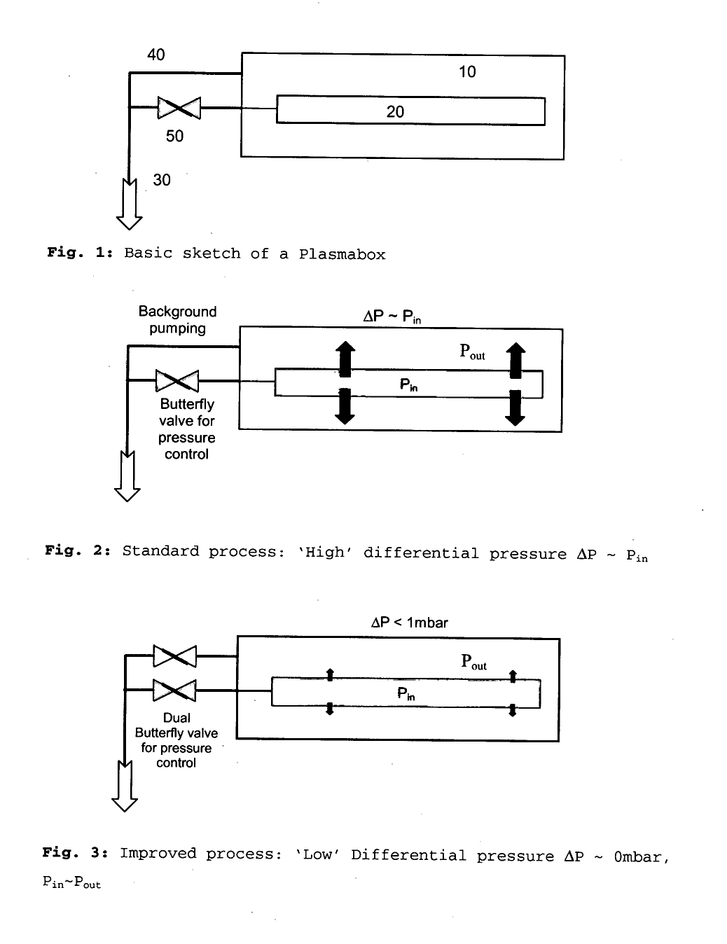

FIG. 2 shows the standard process, where a ‘high’ differential pressure ΔP˜Pᵢₙ is established, in accordance with the teachings of U.S. Pat. No. 4,989,543. The pressure in the outer chamber Pₒᵤₜ<<1 mbar, therefore ΔP=Pᵢₙ−Pₒᵤₜ results in ΔP˜Pᵢₙ.

The improved process according to the invention is shown in FIG. 3 and requires a ‘low’ Differential pressure ΔP˜0 mbar or ΔP<1 mbar, resulting thus in Pᵢₙ˜Pₒᵤₜ.

In order to allow for precise control of the low differential pressure, it is suggested to use two independent butterfly valves, one controlling the exhaust of the outer airtight chamber and one controlling the pressure in the inner non-airtight enclosure or reactor. Depending on the configuration a one or two valve arrangement may be possible, this depends on the configuration of the overall deposition system.

### Example

Deposition conditions for microcrystalline silicon layer in a KAI-M system: 13.56 MHz, interelectrode gap 13 mm, 450 W, 9.0 mbar, 2500 sccm H₂. In study A) a strong differential pumping was applied during deposition resulting in a pressure difference of 8 mbar (i. E. according to FIG. 2). In B) the pumping around the PECVD reactor was reduced to get a pressure difference of only 0.5 mbar while keeping the deposition pressure at 9.0 mbar.

silane concentration has to be compensated for the absence of the usual differential pressure to get the same Raman crystallinity: 38 sccm SiH₄ with (study A), 34 sccm SiH₄ without (study B)

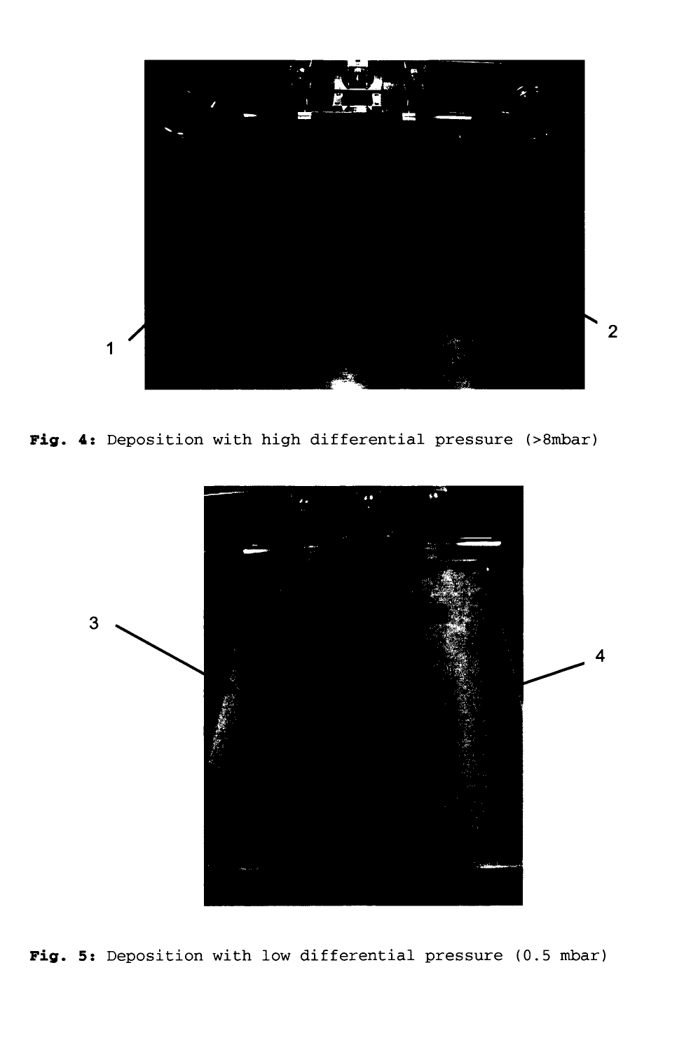

FIG. 4: Deposition with high differential pressure (>8 mbar), where the a-Si:H deposition zone can be clearly identified (Rc <10%), surrounding the pc-Si:H deposition central region (Rc ˜50%). Local inhomogeneity results in significant deposition on side windows located close to reference sign 2, whereas at the window located at region 2 a clean window can be found.

FIG. 5: Deposition with low differential pressure (0.5 mbar) according to an embodiment of the invention, where Raman crystallinity (Rc) is kept well at around 50% (within +/−10%) over the whole substrate area of pc-Si growth. Clean side windows at location 3 and 4 confirm this result.

Implementing the pc-Si:H material of both FIGS. 4 and 5 in a p-i-n device resulted in the same solar cell performances. This indicates that the same material quality is obtained, however in deposition conditions of FIG. 5 at much improved homogeneity.

To grow microcrystalline silicon at high pressures small differential pressures are thus desired for homogeneous growth. Further, it is favourable to control and adjust the pressure around the PECVD Plasmabox to defined functions of the plasma pressure, like Pₒᵤₜ=0.5 Pᵢₙ, Pₒᵤₜ=0.75 Pᵢₙ or Pₒᵤₜ=0.95 Pᵢₙ (ideally controlling from maximum differential pressure to equilibrium).

### Further Advantages of the Invention

Forces applied on the reactor parts from the inside towards the outside can be greatly reduced in high pressure regimes, when the gas pressure difference between the outer vacuum chamber and the inner plasma chamber is reduced, leading to reduced mechanical stress and/or deformation that may also affect leakage rate. A rough estimate of the force exerted on end plates of Plasmabox in a KAI-1200 with a 10 mbar pressure difference is around 140 kg. Improved lifetime and reduced maintenance times may also result from the reduced mechanical force acting onto the equipment.

Leakage rate of one Plasmabox may vary from one to another of the production stack reactor tower leading to discrepancy in deposition regimes used for the growth of microcrystalline silicon, and ultimately increased dispersion in the devices performances from one reactor to another. The solution proposed may as well alleviate this issue by limiting the influence of leakage rate on the plasma conditions.

Adjustment of differential pressure adds an additional degree of freedom to control the transition from amorphous to micro-crystalline silicon, as going from the presence of usual differential pumping to Pₒᵤₜ=Pᵢₙ tends to favor a-Si:H growth.

or

Reducing the differential pressure (to Pₒᵤₜ=Pᵢₙ) allows a better control of the transition from the microcrystalline to amorphous silicon growth over the substrate area as conventional differential pumping favors amorphous growth.

Limited powder formation also facilitates reactor cleaning using existent solutions based on either SF₆, NF₃ or F₂.

1) A method for manufacturing thin films in a deposition system, said system comprising an inner non-airtight enclosure for containing at least one substrate, an outer airtight chamber completely surrounding said enclosure, an exhaust operatively connected to both, keeping said chamber at a pressure lower than the pressure within said enclosure characterized in that, during operation, a pressure difference of less than 1 mbar between inner non-airtight enclosure and outer airtight chamber is being established.

2) A method according to claim 1, wherein it is valid for the differential pressure ΔP=Pᵢₙ−Pₒᵤₜ between pressure in inner enclosure Pᵢₙ and pressure in outer chamber Pₒᵤₜ:Pₒᵤₜ=0.5 Pᵢₙ or Pₒᵤₜ=0.75 Pᵢₙ or Pₒᵤₜ=0.95 Pᵢₙ.

3) A method according claims 1, wherein a microcrystalline silicon layer is being deposited at a pressure in the inner non-airtight chamber of 9 mbar and a pressure difference of 0.5 mbar.

4) An apparatus for producing thin films using a plasma deposition process comprising an inner non-airtight enclosure in which the prevailing pressure is less than the atmospheric pressure for containing at least one substrate; an outer airtight chamber surrounding said enclosure, said chamber being kept at a pressure lower than the pressure within said enclosure; an exhaust operatively connected to both air-tight enclosure and non-airtight chamber, further comprising at least two butterfly vents, arranged between exhaust and inner and outer chamber respectively for controlling the pressure difference between inner enclosure and outer chamber and configured to establish a pressure difference of less than 1 mbar between inner non-airtight enclosure and outer airtight chamber.
